(19) United States
(12) Patent Application Publication
(10) Pub. No.: US 2025/0116722 A1
(43) Pub. Date: Apr. 10, 2025

(54) METHOD OF MONITORING HIGH-VOLTAGE BATTERY OF VEHICLE

(71) Applicants: Hyundai Motor Company, Seoul (KR); Kia Corporation, Seoul (KR)

(72) Inventor: Yong Hyun Kim, Seoul (KR)

(21) Appl. No.: 18/883,880

(22) Filed: Sep. 12, 2024

(30) Foreign Application Priority Data
Oct. 4, 2023 (KR) 10-2023-0131582

(51) Int. Cl. G01R 31/392; B60L 58/16; B60L 58/18; G01R 31/367

(52) U.S. Cl. CPC G01R 31/392; B60L 58/16; B60L 58/18; G01R 31/367

(57) ABSTRACT

A method of monitoring a high-voltage battery provided in an electric vehicle (EV) may check the state of a high-voltage battery and a low-voltage battery, actively perform monitoring at a time when monitoring is required, such as when the low-voltage battery is in good condition and the high-voltage battery is slightly degrading. When an aging state of the high-voltage battery and the low-voltage battery progresses, the method may change accordingly a monitoring repetition period to reduce the power consumption compared to the same monitoring time or reduce the total monitoring time to reduce the power consumption, thereby preventing the low-voltage battery used as an auxiliary battery from being fully discharged.

### CROSS-REFERENCE TO RELATED APPLICATION

This application claims under 35 U.S.C. § 119(a) the benefit of Korean Patent Application No. 10-2023-0131582, filed on Oct. 4, 2023, the entire contents of which are incorporated by reference herein.

### BACKGROUND

### (a) Technical Field

The present disclosure relates to a method of monitoring a high-voltage battery of a vehicle based on a degree of degradation of the battery.

### (b) Description of the Related Art

An electric vehicle (EV) may be referred to as an environmentally friendly vehicle, which uses an electric motor as a driving source for driving the vehicle. For example, referring to FIG. 1, a power system of an EV typically includes: a motor 11; an inverter 12 adapted to drive the motor 11; a high-voltage battery 10 provided as a power source for operating the motor 11; a main relay (MR) adapted to open and close a power supply path between the high-voltage battery 10 and the inverter 12 according to a control signal; a low-voltage battery 15 having a lower voltage than the high-voltage battery 10; a low-voltage direct current-direct current (DC-DC) converter (LDC) 14 adapted to reduce the high-voltage power of the high-voltage battery 10 and provide it to the low-voltage battery 15; and a battery management system (BMS) 13 adapted to control the main relay MR to be turned on or off, as shown in FIG. 1.

The power system of the EV also may include an intelligent high-voltage battery sensor HB_IBS 17A adapted to detect the voltage and current of the high-voltage battery 10 and notify the BMS 13 of this; an intelligent low-voltage battery sensor LB_IBS 17B adapted to detect the voltage and current of the low-voltage battery 15 and notify the LDC 14 of this; and a control unit 16 adapted to control the elements of the power system described above.

For example, the control unit 16 may be a vehicle control unit VCU or a hybrid control unit HCU, but may be collectively referred to as a control unit or controller.

Thus, according to this configuration described above, the LDC 14 may operate while the main relay MR is in an “on” state while the vehicle is driving, and may convert a high-voltage DC voltage from the high-voltage battery 10 or a high-voltage DC voltage of regenerative energy by the motor 11 into a low-voltage DC voltage to charge the low-voltage battery 15 or to supply it to an electrical load.

On the other hand, when the vehicle is left with the power supply off (e.g., IG Off) for a long period of time, a situation where the low-voltage battery 15 is discharged may arise, which may allow dark current to flow through various devices of the electrical load inside the vehicle and may discharge the low-voltage battery 15.

When the low-voltage battery 15 is discharged, most of the controllers and electronic components in the vehicle that receive power from the low-voltage battery 15 may become inoperable. Thus, when the vehicle is left unattended or parked for a long period of time, it is necessary to charge (recharge) the low-voltage battery 15 periodically.

Furthermore, in addition to the dark current described above, one of the main factors that consume or discharge the power of the low-voltage battery 15 after the start is turned off may be a “battery monitoring function during parking” and a “black box function.” Here, the battery monitoring function has an important logic that allows the vehicle to turn on a controller by itself even if the start is turned off and the driver is not in the vehicle and to monitor a high-voltage battery to determine whether there is an abnormality in the cell deviation or insulation resistance of the high-voltage battery and, when it is determined that there is a problem, store such a failure and inform the driver of this to take an emergency measure.

Accordingly, FIG. 2 illustrates, as a waveform, the battery monitoring function during parking according to a typical method, and as shown, after a delay time indicated as “a” after the start is off, monitoring may be performed continuously for 2 hours, and may then be active for 20 seconds each with a monitoring repetition period of 10 minutes to be performed in pulse type. In addition, a total monitoring time may be set to 60 hours.

The delay time indicated as “a” may be eliminated at a system design time.

The battery monitoring function during parking, which operates as described above, may be performed under the control of the BMS 13 and the control unit (i.e., controller) 16 of FIG. 1, which may be considered a periodic battery check logic for preventing a fire that may occur in the high-voltage battery 10. Thus, when a state of health (SOH) of a low-voltage battery is high after the vehicle is first produced, there is no problem but, as the low-voltage battery consumes power correspondingly, it may degrade over time even though the low-voltage battery is charged or recharged. Thus, the probability of discharge increases even if the same amount of time is used for charging.

That is, as shown in FIG. 3, at an initial stage (no aging) after production, a battery may have the same values in an SOH and a state of charge (SOC) but, as the battery is used and aged with a degraded portion increasing, the SOH may be 70% when the degraded portion is substantially 10%, even though the battery is fully charged, i.e., the SOC is 100%.

Actual cases of maintenance and repairs for such a battery discharge problem described above were identified in Europe.

Thus, the statistical probability of a failure of a high-voltage battery may be identified by field claims. According to this, as the high-voltage battery degrades, the risk of fire may decrease.

Therefore, monitoring a battery with the same periods until the scrapping of a vehicle from an initial stage after production, without considering the issues described above, may cause more harm than good. For example, there is a high probability of other adverse issues: due to the power consumed by the monitoring function during parking, an aged low-voltage battery may be discharged, and the start of the vehicle may not operate. Therefore, there is a need to develop a technology to improve this.

### SUMMARY

An object of the present disclosure is to provide a method of monitoring a high-voltage battery of an electric vehicle (EV), which may check the states of the high-voltage battery and a low-voltage battery provided in the electric vehicle, monitor them more actively when monitoring is required, such as, when the low-voltage battery is in good condition and the high-voltage battery is only slightly degraded, and set a wider monitoring repetition period according to a condition in a situation where a monitoring cycle may be delayed after a certain time or under a specific condition, to prevent the low-voltage battery used as an auxiliary battery from being fully discharged.

To solve the preceding technical problems, according to an embodiment of the present disclosure, there is provided a method of monitoring a high-voltage battery of a vehicle, the method comprising in response to the vehicle being in an off state, obtaining, by a controller, a first monitoring cycle based on a state of a low-voltage battery determined according to a first preset threshold value; obtaining, by the controller, a second monitoring cycle based on an aging state of the high-voltage battery determined according to a first preset threshold value; determining, by the controller, a final monitoring cycle based on the first monitoring cycle and the second monitoring cycle; and monitoring, by the controller, the high-voltage battery based on the final monitoring cycle.

According to an embodiment of the present disclosure, the first preset threshold value is set to be equal to or less than 60% with respect to a state of health (SOH).

According to an embodiment of the present disclosure, the obtaining of the first monitoring cycle comprises in response that the state of the low-voltage battery falls to or below the first threshold value, adding a preset additional time to a previous monitoring repetition period to obtain the first monitoring cycle.

According to an embodiment of the present disclosure, the preset additional time ranges from 2% to 50% of the previous monitoring repetition period.

According to an embodiment of the present disclosure, the first threshold value is set to be equal to or below 50% with respect to a state of charge (SOC).

According to an embodiment of the present disclosure, the obtaining of the first monitoring cycle comprises in response that the state of the low-voltage battery falls to or below the first threshold value, adding a preset additional time to a previous monitoring repetition period to obtain the first monitoring cycle.

According to an embodiment of the present disclosure, the preset additional time ranges from 2% to 50% of the previous monitoring repetition period.

According to an embodiment of the present disclosure, the second threshold value comprises a first degradation threshold value, a second degradation threshold value, and a third degradation threshold value with respect to an SOH, the first degradation threshold value greater than the second degradation threshold value and the second degradation threshold value greater than the third degradation threshold value.

According to an embodiment of the present disclosure, the obtaining of the second monitoring cycle further comprises in response that the SOH of the high-voltage battery is less than the first degradation threshold value and greater than or equal to the second degradation threshold value, adding an additional time of 10 seconds to the previous monitoring repetition period to obtain the second monitoring cycle.

According to an embodiment of the present disclosure, the obtaining of the second monitoring cycle further comprises in response that the SOH of the high-voltage battery is less than the second degradation threshold value and greater than or equal to the third degradation threshold value, adding an additional time of 20 seconds to the previous monitoring repetition period to obtain the second monitoring cycle.

According to an embodiment of the present disclosure, the obtaining of the second monitoring cycle further comprises in response that the SOH of the high-voltage battery is less than the second degradation threshold value and greater than or equal to the third degradation threshold value, reducing a total monitoring time.

According to an embodiment of the present disclosure, the obtaining of the second monitoring cycle further comprises in response that the SOH of the high-voltage battery is less than the third degradation threshold value, adding an additional time of 30 seconds to the previous monitoring repetition period to obtain the second monitoring cycle.

According to an embodiment of the present disclosure, the obtaining of the second monitoring cycle further comprises in response that the SOH of the high-voltage battery is less than the third degradation threshold value, reducing a total monitoring time.

According to an embodiment of the present disclosure, the determining of the final monitoring cycle comprises determining, to be the final monitoring cycle, one having a greater difference from a previous monitoring cycle between the first monitoring cycle and the second monitoring cycle.

To solve the preceding technical problems, according to an embodiment of the present disclosure, there is provided a method of monitoring a high-voltage battery of a vehicle, the method comprising in response to the vehicle being in an off state, obtaining, by a controller, a first monitoring cycle based on a state of a low-voltage battery determined according to a preset first threshold value; obtaining, by the controller, a second monitoring cycle based on an aging state of the high-voltage battery determined according to a second preset threshold value; obtaining, by the controller, a third monitoring cycle based on an aging state of the high-voltage battery determined according to a third preset threshold value; determining, by the controller, a final monitoring cycle based on the first monitoring cycle, the second monitoring cycle, and the third monitoring cycle; and monitoring, by the controller, the high-voltage battery based on the final monitoring cycle.

According to an embodiment of the present disclosure, the third threshold value is set to a preset hours in a real-time clock (RTC).

According to an embodiment of the present disclosure, the obtaining of the third monitoring cycle further comprises in response that the RTC of the high-voltage battery reaches the third threshold value, adding an additional time of 2% to 50% to a previous monitoring repetition period to obtain the third monitoring cycle.

According to an embodiment of the present disclosure, the obtaining of the third monitoring cycle further comprises in response that the RTC of the high-voltage battery reaches the third threshold value, reducing a total monitoring time to obtain the third monitoring cycle.

According to an embodiment of the present disclosure, the determining of the final monitoring cycle comprises determining, to be the final monitoring cycle, one having a greatest difference from the monitoring cycle, among the first monitoring cycle, the second monitoring cycle, and the third monitoring cycle.

The method of monitoring a high-voltage battery of a vehicle according to embodiments of the present disclosure described herein may check the states of a high-voltage battery and a low-voltage battery provided in an electric vehicle; monitor them more actively when monitoring is required, such as, when the low-voltage battery is in good condition and the high-voltage battery is only slightly degraded; and change a monitoring repetition period according to the aging state of the low-voltage battery and the high-voltage battery to reduce the power consumption compared to the same monitoring time, or reduce a total monitoring time to reduce the power consumption, thereby preventing the low-voltage battery used as an auxiliary battery from being fully discharged.

According to embodiments of the present disclosure, a non-transitory computer readable medium containing program instructions executed by a processor may include: in response to a vehicle being in an off state, program instructions that obtain a first monitoring cycle based on a state of a low-voltage battery determined according to a first preset threshold value; program instructions that obtain a second monitoring cycle based on an aging state of the high-voltage battery determined according to a first preset threshold value; program instructions that determine a final monitoring cycle based on the first monitoring cycle and the second monitoring cycle; and program instructions that monitor the high-voltage battery based on the final monitoring cycle.

### BRIEF DESCRIPTION OF THE DRAWINGS

FIG. 1 is a diagram illustrating an example power system of an electric vehicle (EV).

FIG. 2 is a diagram illustrating an example waveform provided to describe a typical method of monitoring a high-voltage battery.

FIG. 3 is a diagram illustrating the concepts of a state of charge (SOC) and a state of health (SOH).

FIGS. 4A-4B are a flowchart illustrating a method of monitoring a high-voltage battery of a vehicle according to an embodiment of the present disclosure.

FIGS. 5A-5B are a flowchart illustrating a method of monitoring a high-voltage battery of a vehicle according to another embodiment of the present disclosure.

### DETAILED DESCRIPTION OF THE DISCLOSURE

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Hereinafter, embodiments of the present disclosure will be described in detail with reference to the accompanying drawings. The embodiments are not construed as limited to the disclosure and should be understood to include all changes, equivalents, and replacements within the idea and the technical scope of the disclosure.

The terms “module,” “unit,” and/or “-er/or” for referring to elements are assigned and used interchangeably in consideration of the convenience of description, and thus the terms per se do not necessarily have different meanings or functions. The terms “module,” “unit,” and/or “-er/or” do not necessarily require physical separation.

Although terms including ordinal numbers, such as “first,” “second,” and the like, may be used herein to describe various elements, the elements are not limited by these terms. These terms are only used to distinguish one element from another.

The term “and/or” is used to include any combination of multiple items that are subject to it. For example, “A and/or B” may include all three cases, for example, “A,” “B,” and “A and B.”

When an element is described as “coupled” or “connected” to another element, the element may be directly coupled or connected to the other element. However, it is to be understood that another element may be present therebetween. In contrast, when an element is described as “directly coupled” or “directly connected” to another element, it is to be understood that there are no other elements therebetween.

Unless otherwise defined, all terms including technical and scientific terms used herein have the same meaning as commonly understood by one of ordinary skill in the art to which the present disclosure pertains. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

In addition, the term “unit” or “control unit” is merely a widely used term for naming a controller that controls a specific vehicle function, and does not mean a generic functional unit.

For example, each controller may include a communication device that communicates with another controller or a sensor to control a function assigned thereto, a memory that stores an operating system (OS), a logic command, input/output information, and the like, and one or more processors that perform determination, calculation, decision, and the like that are necessary for controlling a function assigned thereto.

Meanwhile, a processor may include a semiconductor integrated circuit and/or electronic devices that perform at least one or more of comparison, determination, computation, operations, and decision to achieve programmed functions. The processor may be, for example, any one or a combination of a computer, a microprocessor, a central processing unit (CPU), an application-specific integrated circuit (ASIC), and an electronic circuit (e.g., circuitry and logic circuits).

In addition, computer-readable recording media (or simply memory) include all types of storage devices that store data readable by a computer system. The storage devices may include at least one type of, for example, flash memory, hard disk, micro-type memory, card-type (e.g., secure digital (SD) card or extreme digital (XD) card) memory, random-access memory (RAM), static RAM (SRAM), read-only memory (ROM), programmable ROM (PROM), electrically erasable PROM (EEPROM), magnetic RAM (MRAM), magnetic disk, or optical disc.

This recording medium may be electrically connected to the processor, and the processor may load and record data from the recording medium. The recording medium and the processor may be integrated or may be physically separated.

Hereinafter, a method of monitoring a high-voltage battery of a vehicle will be described with reference to the accompanying drawings.

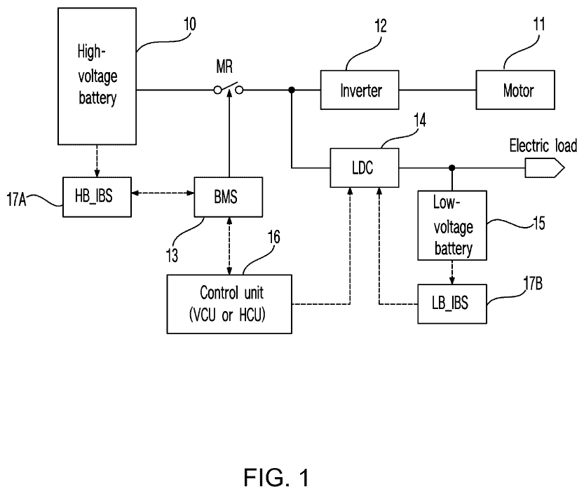

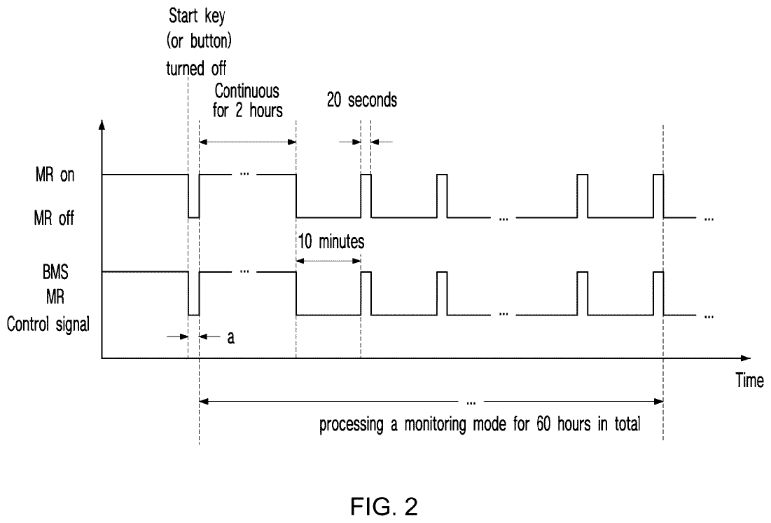

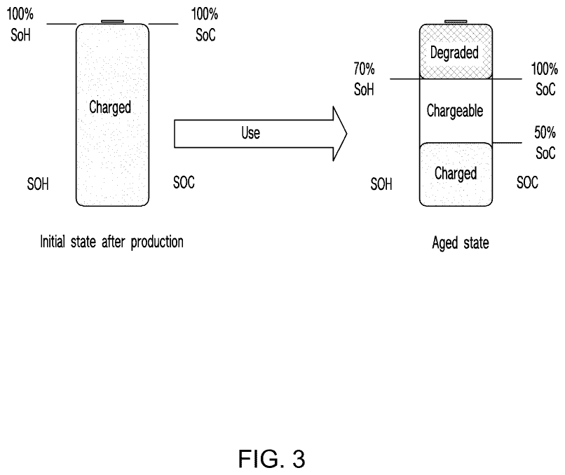

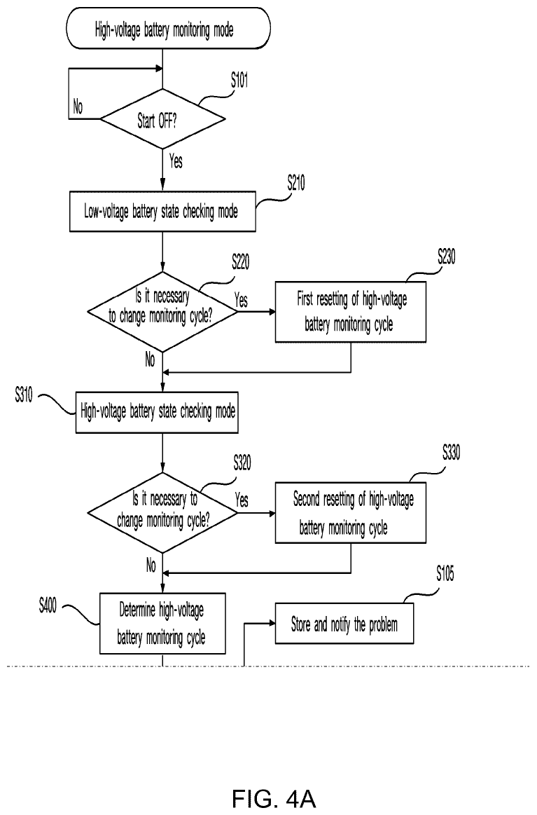

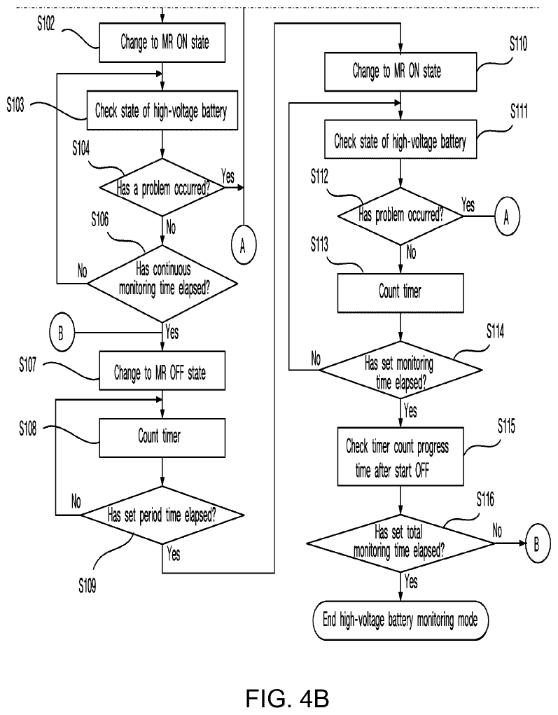

FIGS. 4A-4B are a flowchart illustrating a method of monitoring a high-voltage battery of a vehicle according to an embodiment of the present disclosure. The method will be described with reference to FIGS. 1 and 2.

The control unit (or controller) 16 is configured to perform the monitoring and/or control functions as described herein. The control unit 16 may constitute modules and/or devices of the vehicle, which may include one or more controllers. For example, the control unit 16 of the vehicle may constitute hardware components that form part of a controller (e.g., modules or devices of a high-level controller), or may constitute individual controllers each having a processor and memory. The vehicle may include one or more processors and memory.

For ease of the description of embodiments of the present disclosure, each portion of the waveform shown in the FIG. 2 will be referred to and described as follows: an area indicated as “continuous for 2 hours” may represent a “continuous monitoring time.” In addition, an interval indicated as “10 minutes” may represent a “monitoring repetition period,” an interval indicated as “20 seconds” may represent a “monitoring time,” and a section indicated as a “monitoring mode of a total of 60 hours” may represent a “total monitoring time.” The waveform shown in FIG. 2 may represent a “monitoring cycle.”

In step S101, a driver of the vehicle may determine whether the start of the vehicle is switched to an off state.

When it is determined that the start of the vehicle has been switched to the off state in step S101, step S210 may be performed to detect and check a state of the low-voltage battery 15 through LB_IBS 17B.

Subsequently, in step S220, whether the state of the low-voltage battery 15 detected in step S210 is detected to be 60% or less based on a state of health (SOH) or 50% or less based on a state of charge (SOC) may be determined.

That is, when an SOH value of the low-voltage battery 15 is 60% or less based on the SOH or an SOC value of the low-voltage battery 15 is 50% or less based on the SOC in step S220, it may be determined that there is a need to change a monitoring cycle, and step S230 may then be performed.

In step S230, a first changing and setting process to change and set the monitoring cycle for the high-voltage battery 10 may be performed. In detail, in this first changing and setting process, based on the SOH, when the SOH of the low-voltage battery 15 falls to 60% or less, it may be determined that changing an interval of a monitoring repetition period is necessary, and a preset additional time ranging from 2% to 50% may be added to the monitoring repetition period. That is, for example, the existing monitoring repetition period of 10 minutes may be changed to any time between 10 minutes 12 seconds and 15 minutes.

On the other hand, based on the SOC, when the SOC of the low-voltage battery 15 falls to 50% or less, it may also be determined that changing the interval of the monitoring repetition period is necessary.

Thus, in a case where the number of repetitions of monitoring is assumed without considering a set monitoring time of 20 seconds, under the same total monitoring time as before, for the convenience of calculation, a total of 348 repetitions of monitoring with the existing monitoring repetition period of 10 minutes may be changed to a total of 232 repetitions of monitoring with a changed monitoring repetition period of 15 minutes (50% added).

Accordingly, the power consumption of the low-voltage battery 15 may be reduced in proportion to the reduced number of repetitions of monitoring.

When it is determined in step S220 that the state of the low-voltage battery 15 is good and no change in the monitoring cycle is required, step S310 may be performed after step S230 is performed, and the state of the high-voltage battery 10 may be detected and checked through HB_IBS 17A.

Once the state of the high-voltage battery 10 has been checked in step S310, step S320 may be performed to determine whether a change in the monitoring cycle is required.

In step S320, the state of the high-voltage battery 10 may be determined based on a first degradation threshold value set to 80% based on the SOH, a second degradation threshold value set to 60% based on the SOH, and a third degradation threshold value set to 40% based on the SOH.

That is, when it is determined in step S320 that the state of the high-voltage battery 10 corresponds to a value of 80% or more based on the SOH, it may be determined that no change in the monitoring cycle is required, and step S400 may then be performed.

In contrast, when it is determined in step S320 that the state of the high-voltage battery 10 corresponds to a value of less than 80% based on the SOH, it may be determined that a change in the monitoring cycle is required, and step S330 may then be performed.

In step S330, when the SOH of the high-voltage battery 10 is less than the first degradation threshold value and greater than or equal to the second degradation threshold value, i.e., when the SOH of the high-voltage battery 10 is greater than or equal to 60% and less than 80%, an additional time of 10 seconds may be added to the monitoring repetition period.

In contrast, when the SOH of the high-voltage battery 10 is less than the second degradation threshold value and greater than or equal to the third degradation threshold value, i.e., when the SOH of the high-voltage battery 10 is less than 60% and greater than or equal to 40%, an additional time of 20 seconds may be added to the monitoring repetition period.

In addition, when the SOH of the high-voltage battery 10 is less than the second degradation threshold value and greater than or equal to the third degradation threshold value, i.e., when the SOH of the high-voltage battery 10 is less than 60% and greater than or equal to 40%, the total monitoring time may be reduced by 40% to change the total monitoring time to 36 hours, which may reduce the power consumed for monitoring.

Thus, when the SOH of the high-voltage battery 10 is less than 60% and greater than or equal to 40%, an additional time of 20 seconds may be added to the monitoring repetition period or the total monitoring time may be changed to 36 hours, which may be selected or combined by the engineering designer.

In addition, when the SOH of the high-voltage battery 10 is less than the third degradation threshold value, i.e., when the SOH of the high-voltage battery 10 is less than 40%, an additional time of 30 seconds may be added to the monitoring repetition period, or the total monitoring time may be reduced by 60% to 24 hours.

In this case, the additional time of 30 seconds may be added to the monitoring repetition period, or the total monitoring time may be changed to 24 hours, which may be selected or combined by the engineering designer.

Subsequently, in step S400, both a value for the monitoring cycle that has changed based on the state of the low-voltage battery 15 in steps S210 through S230 described above and a value for the monitoring cycle that has changed based on the state of the high-voltage battery 10 in steps S310 through S330 described above may be received and combined to determine the monitoring cycle for the high-voltage battery 10.

In this case, in step S400, when combining the value for the monitoring cycle changed according to the state of the low-voltage battery 15 and the value for the monitoring cycle changed according to the state of the high-voltage battery 10, a greater change for the same change target may be first applied to be combined.

When the monitoring cycle is determined based on the state of the low-voltage battery 15 and the high-voltage battery 10 in step S400, step S103 may be performed, after step S102 is performed, to turn on a relay (MR) to monitor the state of the high-voltage battery 10.

In this case, the state of the high-voltage battery 10 may be checked to determine whether there is an abnormality in a deviation or insulation resistance of cells included in the high-voltage battery 10.

Whether there is a problem in the state of the high-voltage battery 10 checked in step S103 may be determined in step S104. In this case, when it is determined that there is a problem, step S105 may be performed to store the problem and notify the driver (or owner) of this problem.

When it is determined in step S104 that no problem has occurred, step S106 may be performed to determine whether a continuous monitoring time set to 2 hours has elapsed.

When it is determined in step S106 that the continuous monitoring time has not elapsed, step S103 may be performed again, and when it is determined in step S106 that the continuous monitoring time has elapsed, step S107 may be performed.

In step S107, the relay MR may be turned off, and step S108 may then be performed to count a timer.

In step S109, the time counted in step S108 may be used to determine whether a time of the monitoring repetition period according to the monitoring cycle determined in step S400 has elapsed, and when it is determined that the set monitoring repetition period has been reached, step S110 may be performed to turn on the relay MR.

Subsequently, in step S111, monitoring may be performed to check the state of the high-voltage battery 10.

Whether there is a problem in the state of the high-voltage battery 10 checked in step S111 may be determined in step S112. In this case, when it is determined that there is a problem, step S105 may be performed to store the problem and notify the driver (or owner) of this problem.

When it is determined in step S112 that no problem has occurred, step S113 may be performed to determine whether the monitoring time preset to 20 seconds has elapsed.

When it is determined in step S113 that the monitoring time has not elapsed, step S111 may be performed again, and when it is determined that the monitoring time has elapsed, step S115 may then be performed.

In step S115, a progress time of the timer after the start is off in step S101 may be checked in step S116, and in step S116, whether the total monitoring time determined in step S400 has elapsed may be determined. In this case, when it is determined that the determined total monitoring time has not elapsed, step S107 may be performed again, and when it is determined that the determined total monitoring time has elapsed, a high-voltage battery monitoring mode may be terminated.

Thus, a monitoring cycle (e.g., the monitoring cycle determined in step S400) may be changed according to the degree of aging of a high-voltage battery and a low-voltage battery after the release of an electric vehicle (EV) as a new product. In addition, the monitoring cycle of the high-voltage battery may be changed adaptively according to the degree of aging of the low-voltage battery or the high-voltage battery (for example, also in a case where the driver replaces the low-voltage battery or the high-voltage battery with a new one), and thus a discharge time of the low-voltage battery to be consumed to maintain the monitoring cycle may be fixed.

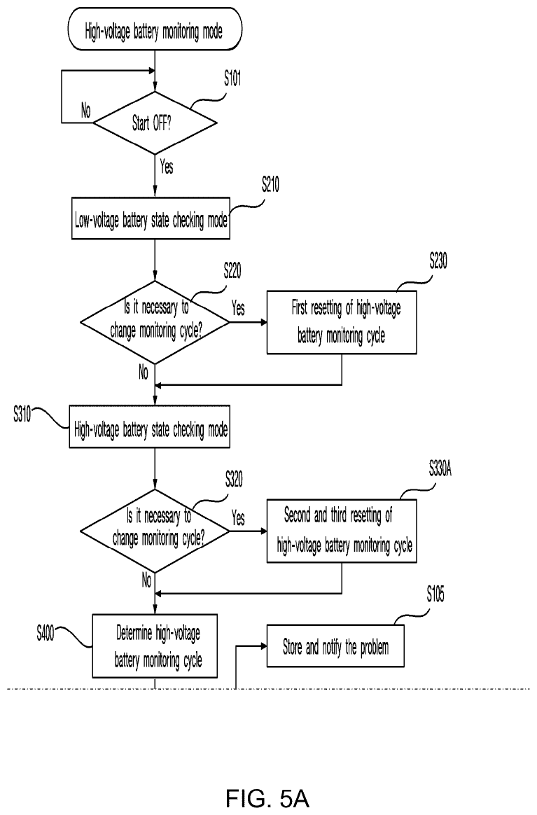

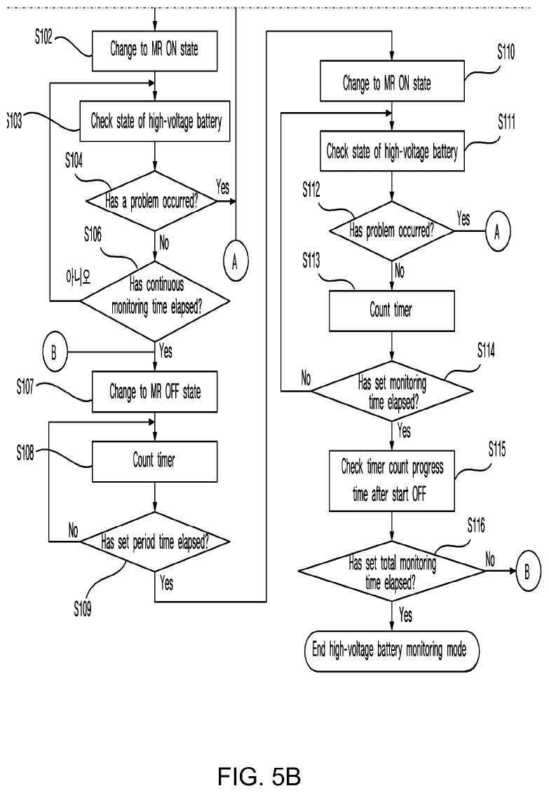

FIGS. 5A-5B are a flowchart illustrating a method of monitoring a high-voltage battery of a vehicle according to another embodiment of the present disclosure. The method described with reference to FIGS. 5A-5B may be different from the method described above with reference to FIGS. 4A-4B in that FIG. 5A includes step S330A.

In such an added step S330A, a real-time clock (RTC) may be added as a criterion for determining whether the high-voltage battery 10 is aging, which is set to 8,760 hours based on the RTC. When the RTC of the high-voltage battery 10 is 8,760 hours or more, an additional time of 10% to 50% may be added to the monitoring repetition period to reduce the number of repetitions of monitoring compared to the total monitoring time.

In addition, when the RTC of the high-voltage battery is 8,760 hours or more, the total monitoring time may be reduced by 50% to reduce the power consumed for monitoring.

While desirable embodiments of the present disclosure have been shown and described above. it will be apparent to one of ordinary skill in the art that various modifications or changes in form and details may be made in these embodiments without departing from the spirit and scope of the claims and their equivalents.

What is claimed is:

1. A method of monitoring a high-voltage battery of a vehicle, the method comprising:
in response to the vehicle being in an off state, obtaining, by a controller, a first monitoring cycle based on a state of a low-voltage battery determined according to a first preset threshold value;
obtaining, by the controller, a second monitoring cycle based on an aging state of the high-voltage battery determined according to a first preset threshold value;
determining, by the controller, a final monitoring cycle based on the first monitoring cycle and the second monitoring cycle; and
monitoring, by the controller, the high-voltage battery based on the final monitoring cycle.

2. The method of claim 1, wherein the first preset threshold value is set to be equal to or less than 60% with respect to a state of health (SOH).

3. The method of claim 2, wherein obtaining the first monitoring cycle comprises:
in response to the state of the low-voltage battery falling at or below the first threshold value, adding a preset additional time to a previous monitoring repetition period to obtain the first monitoring cycle.

4. The method of claim 3, wherein the preset additional time ranges from 2% to 50% of the previous monitoring repetition period.

5. The method of claim 1, wherein the first threshold value is set to be equal to or below 50% with respect to a state of charge (SOC).

6. The method of claim 5, wherein obtaining the first monitoring cycle comprises:
in response to the state of the low-voltage battery falling at or below the first threshold value, adding a preset additional time to a previous monitoring repetition period to obtain the first monitoring cycle.

7. The method of claim 5, wherein the preset additional time ranges from 2% to 50% of the previous monitoring repetition period.

8. The method of claim 1, wherein the second threshold value comprises a first degradation threshold value, a second degradation threshold value, and a third degradation threshold value with respect to an SOH, the first degradation threshold value greater than the second degradation threshold value and the second degradation threshold value greater than the third degradation threshold value.

9. The method of claim 8, wherein obtaining the second monitoring cycle further comprises:
in response to the SOH of the high-voltage battery being less than the first degradation threshold value and greater than or equal to the second degradation threshold value, adding an additional time of 10 seconds to the previous monitoring repetition period to obtain the second monitoring cycle.

10. The method of claim 8, wherein obtaining the second monitoring cycle further comprises:
in response to the SOH of the high-voltage battery being less than the second degradation threshold value and greater than or equal to the third degradation threshold value, adding an additional time of 20 seconds to the previous monitoring repetition period to obtain the second monitoring cycle.

11. The method of claim 10, wherein obtaining the second monitoring cycle further comprises:
in response to the SOH of the high-voltage battery being less than the second degradation threshold value and greater than or equal to the third degradation threshold value, reducing a total monitoring time.

12. The method of claim 8, wherein obtaining the second monitoring cycle further comprises:
in response to the SOH of the high-voltage battery being less than the third degradation threshold value, adding an additional time of 30 seconds to the previous monitoring repetition period to obtain the second monitoring cycle.

13. The method of claim 12, wherein obtaining the second monitoring cycle further comprises:
in response to the SOH of the high-voltage battery being less than the third degradation threshold value, reducing a total monitoring time.

14. The method of claim 1, wherein determining the final monitoring cycle comprises:
determining, to be the final monitoring cycle, one having a greater difference from a previous monitoring cycle between the first monitoring cycle and the second monitoring cycle.

15. A method of monitoring a high-voltage battery of a vehicle, the method comprising:
in response to the vehicle being in an off state, obtaining, by a controller, a first monitoring cycle based on a state of a low-voltage battery determined according to a preset first threshold value;
obtaining, by the controller, a second monitoring cycle based on an aging state of the high-voltage battery determined according to a second preset threshold value;
obtaining, by the controller, a third monitoring cycle based on an aging state of the high-voltage battery determined according to a third preset threshold value;
determining, by the controller, a final monitoring cycle based on the first monitoring cycle, the second monitoring cycle, and the third monitoring cycle; and
monitoring, by the controller, the high-voltage battery based on the final monitoring cycle.

16. The method of claim 15, wherein the third threshold value is set to a preset hours in a real-time clock (RTC).

17. The method of claim 16, wherein obtaining the third monitoring cycle further comprises:
in response to the RTC of the high-voltage battery reaching the third threshold value, adding an additional time of 2% to 50% to a previous monitoring repetition period to obtain the third monitoring cycle.

18. The method of claim 16, wherein obtaining the third monitoring cycle further comprises:
in response to the RTC of the high-voltage battery reaching the third threshold value, reducing a total monitoring time to obtain the third monitoring cycle.

19. The method of claim 15, wherein determining the final monitoring cycle comprises:
determining, to be the final monitoring cycle, one having a greatest difference from the monitoring cycle, among the first monitoring cycle, the second monitoring cycle, and the third monitoring cycle.

20. A non-transitory computer readable medium containing program instructions executed by a processor, the computer readable medium comprising:
in response to a vehicle being in an off state, program instructions that obtain a first monitoring cycle based on a state of a low-voltage battery determined according to a first preset threshold value;
program instructions that obtain a second monitoring cycle based on an aging state of the high-voltage battery determined according to a first preset threshold value;
program instructions that determine a final monitoring cycle based on the first monitoring cycle and the second monitoring cycle; and
program instructions that monitor the high-voltage battery based on the final monitoring cycle.
